(19) United States
(12) Patent Application Publication
(10) Pub. No.: US 2009/0115642 A1
(43) Pub. Date: May 7, 2009

(54) DEVICE ACTUATED BY KEY OPERATIONS

(76) Inventors: Tetsuji Omura, Ohagki-shi (JP); Nobuyuki Higashiyama, Osaka (JP); Hideki Mizuhara, Ichinomiya-shi (JP)

Correspondence Address: MCDERMOTT WILL & EMERY LLP, 600 13TH STREET, N.W., WASHINGTON, DC, 20005-3096, US

(21) Appl. No.: 12/263,192

(22) Filed: Oct. 31, 2008

(30) Foreign Application Priority Data
Oct. 31, 2007 (JP) 2007-284592
Oct. 31, 2007 (JP) 2007-284595

(51) Int. Cl. H03K 17/94

(52) U.S. Cl. 341/22

(57) ABSTRACT

A PDA as an apparatus actuated by key operations comprises: a substrate; an exothermic semiconductor device provided on a first major surface of the substrate; a plurality of switches provided on a second major surface of the substrate; a key mat located on the side of the second major surface of the substrate; a plurality of pressure conveying portions protruding from one of the major surfaces of the key mat toward each of the plurality of switches, the one of the major surfaces facing the second major surface of the substrate; and a key that is provided on the other major surface of the key mat and that can be pressed down to the key mat. A contact face between the particular switch located within a certain range of the distance from the semiconductor device, and the pressure conveying portion corresponding to the particular switch, has a smaller area as compared to that of a contact face between the non-particular switch, which is a switch other than the particular switch, and the pressure conveying portion corresponding to the non-particular switch.

### CROSS-REFERENCE TO RELATED APPLICATIONS

This application is based upon and claims the benefit of priority from the prior Japanese Patent Applications No. 2007-284592, filed Oct. 31, 2007, and Japanese Patent Application No. 2007-284595, filed Oct. 31, 2007, the entire contents of which are incorporated herein by reference.

### BACKGROUND OF THE INVENTION

1. Field of the Invention

The present invention relates to apparatuses actuated by key operations including: portable apparatuses, such as a personal digital assistant (PDA), a digital still camera (DSC), a digital camcorder (DVC), an electronic dictionary, and a notebook computer; and non-portable apparatuses, such as a desktop personal computer.

2. Description of the Related Art

Apparatuses that are actuated by key operations including portable apparatuses, such as a PDA, and non-portable apparatuses, such as a desktop personal computer, are provided with a plurality of keys on the surface of their cases, and are structured so as to be actuated by pressing down the keys.

With regard to structures of such keys, the following structure is known. That is a button key formed into one body, which is arranged so as to face a central switch and a plurality of surrounding switches provided around the central switch; and has a structure in which the central key can be actuated by an action of pressing down the central portion of the button key, and the surrounding switches can be actuated by actions of pressing down the surrounding portion thereof. In such a structure, among a plurality of pressure conveying projected portions protruding from the button key toward each of the switches, the central pressure conveying projected portion is formed so as to have a slightly greater height than that of the surrounding pressure conveying projected portions. With this, when the central portion of the button key is pressed down, only the central switch is actuated without the surrounding pressure conveying projected portions actuating the surrounding switches.

On these apparatuses, semiconductor devices, such as a CPU for actuating an apparatus, are mounted. Most of the semiconductor devices generate heat while apparatuses are being actuated. The heat generated by an exothermic semiconductor device is conducted from a switch on the substrate to the key side through the pressure conveying projected portion arranged so as to face the switches. Due to this, the key portion located near the semiconductor device that is a heat generator, or heat releasing member, particularly rises in temperature locally. Therefore, there has been the fear that a user sweats from his/her hand or fingers by key operations, making the user feel discomfort.

In addition, when the keys are arranged in a portion where a user of the apparatus holds it, there has been the fear that the user's sweats are present between the device body and the user's hand, which makes the grip performance and the operability of the apparatus poor.

### SUMMARY OF THE INVENTION

The present invention has been made in view of these circumstances, and a general purpose of the invention is to provide a technique in which a local rise in temperature in the key portion can be suppressed in an apparatus provided with a plurality of keys.

To address the problem stated above, an apparatus according to an embodiment of the present invention comprises: a substrate; a heat generator provided directly or via a spacer on a first major surface of the substrate; a plurality of switches that are provided on a second major surface of the substrate and that serve as connecting a contact point when pressed; a key mat that is located on the side of the second major surface of the substrate and made of an elastic member; a plurality of pressure conveying portions that are provided at positions corresponding to each of the plurality of switches, and that are provided between the second major surface of the substrate and one of the major surfaces of the key mat, the one of the major surface facing the second major surface of the substrate; and a key that is provided on the other major surface of the key mat and that can be pressed down to the key mat, wherein a contact face between the pressure conveying portion corresponding to a particular switch located within a certain range of the distance from the heat generator directly fixed to the substrate or from the spacer, in the planar direction of the substrate, and the particular switch, has a smaller area as compared to that of a contact face between the pressure conveying portion corresponding to a non-particular switch, which is a switch other than the particular switch, and the non-particular switch; or wherein a contact face between the pressure conveying portion corresponding to the particular switch and the key mat, has a smaller area as compared to that of a contact face between the pressure conveying portion corresponding to the non-particular switch and the key mat.

In the above embodiment, the plurality of pressure conveying portions are a plurality of projected portions protruding from one of the major surfaces of the key mat, the one of the major surface facing the second major surface of the substrate, toward each of the plurality of switches; and a contact face between the particular switch located within a certain range of the distance from the heat generator directly fixed to the substrate or from the spacer, in the planar direction of the substrate, and the projected portion protruding toward the particular switch, may have a smaller area as compared to that of a contact face between the non-particular switch, which is a switch other than the particular switch, and the projected portion protruding toward the non-particular switch.

In the above embodiment, the plurality of pressure conveying portions are a plurality of projected portions protruding from each of the plurality of keys toward one of the major surfaces of the key mat, the one of the major surfaces facing the second major surface of the substrate; and a contact face between the projected portion protruding from the particular switch located within a certain range of the distance from the heat generator directly fixed to the substrate or from the space, in the planar direction of the substrate, and the key mat, may have a smaller area as compared to that of a contact face between the projected portion protruding from the non-particular switch, which is a switch other than the particular switch, and the key mat.

In the above embodiment, the heat generator may be an exothermic semiconductor device.

In the above embodiment, the heat generator may be a power source.

An apparatus according to another embodiment of the present invention comprises: a substrate; a heat generator provided directly or via a spacer on a first major surface of the substrate; a plurality of switches that are provided on a second major surface of the substrate, and that serve as connecting a contact point when pressed; a key mat that is located on the side of the second major surface of the substrate and made of an elastic member; a plurality of pressure conveying portions that are provided at positions corresponding to each of the plurality of switches, and are provided between the second major surface of the substrate and one of the major surfaces of the key mat, the one of the major surfaces facing the second major surface of the substrate; and a key that is provided on the other side of the major surface of the key mat, and that can be pressed down to the key mat, wherein a gap is provided between the pressure conveying portion corresponding to the particular switch located within a certain range of the distance from the generator directly fixed to the substrate or from the spacer, in the planar direction of the substrate, and the particular switch or the key mat; and wherein the pressure conveying portion corresponding to a non-particular switch, which is a switch other than the particular switch, is in contact with the non-particular switch and the key mat.

In the above embodiment, the plurality of pressure conveying portions are a plurality of projected portions protruding from one of the major surfaces of the key mat, the one of the major surfaces facing the second major surface of the substrate, toward each of the plurality of switches; and a gap may be provided between the particular switch located within a certain range of the distance from the heat generator directly fixed to the substrate or from the space, in the planar direction of the substrate, and the projected portion protruding toward the particular switch; and the non-particular switch, which is a switch other than the particular switch, and the projected portion protruding toward the non-particular switch may be in contact with each other.

In the above embodiment, the plurality of pressure conveying portions are a plurality of projected portions protruding from each of the plurality of switches toward one of the major surfaces of the key mat, the one of the major surfaces facing the second major surface of the substrate; and a gap may be provided between the projected portion protruding from the particular switch located within a certain distance from the heat generator directly fixed to the substrate or from the spacer, in the planar direction of the substrate, and the key mat; and the projected portion protruding from the non-particular switch, which is a switch other than the particular switch, and the key mat may be in contact with each other.

In the above embodiment, the heat generator may be an exothermic semiconductor device.

In the above embodiment, the heat generator may be a power source.

In the above embodiment, the particular switch located within a certain range may be a switch that is located at the smallest distance from the heat generator directly fixed to the substrate or from the spacer, in the planar direction of the substrate.

In the above embodiment, a contact face between the pressure conveying portion corresponding to the non-particular switch that is adjacent to the particular switch, and the non-particular switch, may have a larger area as compared to that of a contact face between the pressure conveying portion corresponding to other switch, and the other switch; or a contact face between the pressure conveying portion corresponding to the non-particular switch, and the key mat, may have a larger area as compared to that of a contact face between the pressure conveying portion corresponding to other switch, and the key mat.

### BRIEF DESCRIPTION OF THE DRAWINGS

FIG. 1 is a schematic view illustrating the exterior structure of a personal digital assistant (PDA) directed to Embodiment 1;

FIG. 2 is a schematic partial cross-sectional view taken along line “A-A” of the PDA illustrated in FIG. 1;

FIG. 3 is a schematic partial cross-sectional view illustrating a shape in which the key and the key mat are formed into one body;

FIGS. 4A-4F are schematic cross-sectional views illustrating shapes of the projected portions protruding toward the particular switch;

FIG. 5 is a schematic partial cross-sectional view illustrating the case where two or more of switches are included within a certain distance from the semiconductor device;

FIG. 6 is a schematic partial cross-sectional view of the apparatus directed to Embodiment 2;

FIGS. 7A-7B are schematic partial cross-sectional views of the apparatus directed to Embodiment 3;

FIG. 8 is a schematic view illustrating the exterior structure of the portable phone directed to Embodiment 4;

FIG. 9 is an exploded perspective view illustrating a major structural portion of the operating unit of the portable phone;

FIG. 10 is a schematic partial cross-sectional view taken along line “A-A” of the PDA illustrated in FIG. 1;

FIG. 11 is a schematic partial cross-sectional view illustrating a shape in which the key and the key mat are formed into one body;

FIGS. 12A-12F are schematic cross-sectional views illustrating a shape of the projected portion protruding from the particular switch;

FIG. 13 is a schematic partial cross-sectional view illustrating the case where two or more switches are included within a certain distance from the semiconductor device;

FIG. 14 is a schematic partial cross-sectional view illustrating the apparatus directed to Embodiment 2;

FIGS. 15A-15B are schematic partial cross-sectional views illustrating the apparatus directed to Embodiment 3;

FIG. 16 is an exploded perspective view illustrating a major structural portion of the operating unit of the portable phone;

FIG. 17 is a schematic view illustrating the exterior structure of a digital still camera;

FIG. 18 is a schematic view illustrating the exterior structure of a digital camcorder;

FIG. 19 is a schematic view illustrating the exterior structure of a non-folding type electronic dictionary or electronic note book;

FIG. 20 is a schematic partial cross-sectional view illustrating a structure in which the battery is arranged on the side of the first major surface of the substrate; and

FIG. 21 is a schematic partial cross-sectional view illustrating a structure in which the battery is arranged on the side of the first major surface of a substrate.

### DETAILED DESCRIPTION OF THE INVENTION

The invention will now be described by reference to the preferred embodiments. This does not intend to limit the scope of the present invention, but to exemplify the invention.

Hereinafter, the present invention will de described with reference to the drawings based on the preferred embodiment of the invention. The same or like components, members, or processes illustrated in each drawing are denoted by like reference numerals, and the duplicative descriptions will be appropriately omitted. The embodiments are not intended to limit the invention but to serve as particular examples thereof, and all features or combinations thereof described there are not always essential to the present invention.

### Embodiment 1

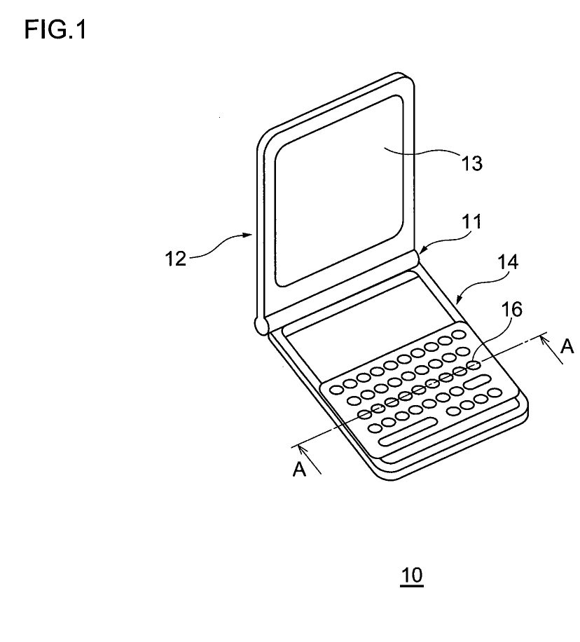

FIG. 1 is a schematic view illustrating the exterior structure of a personal digital assistance (PDA) directed to Embodiment 1. In the present Embodiment, the PDA is exemplified as an apparatus that is actuated by key operations, hence, the PDA may also be, for example: a portable apparatus, such as a digital still camera (DSC), a digital camcorder (DVC), an electronic dictionary, and a notebook computer; or may also be a non-portable apparatus, such as a desktop personal computer.

As illustrated in FIG. 1, the PDA 10 has a structure in which the display unit 12 and the operating unit 14 are connected pivotally by the hinge unit 11. The display unit 12 is provided with the display panel 13 composed of the liquid crystal display (LCD) or the like. On the operating unit 14, a plurality of the keys 16 for giving commands to execute a variety of performances for the PDA 10, or for inputting characters or the like, are arranged.

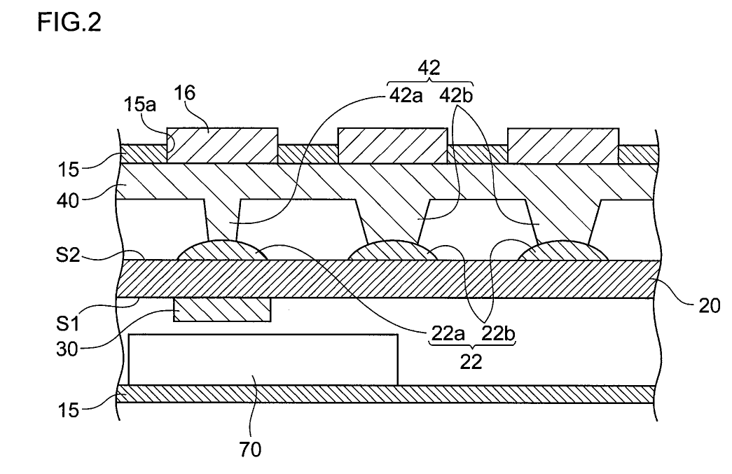

FIG. 2 is a schematic partial cross-sectional view taken along line “A-A” of the PDA illustrated in FIG. 1.

As illustrated in FIG. 2, the substrate 20 on the first major surface S1 of which the exothermic semiconductor device 30 is mounted, is arranged inside the case 15 of the operating unit of the PDA 10. The semiconductor device 30 is an example of a heat generator, or heat releasing member. A plurality of the switches 22, which serve as connecting a contact point when pressed, are provided on the second major surface S2 on the other side of the first major surface S1 of the substrate 20. The key mat 40 made of an elastic member is arranged on the side of the second major surface S2 of the substrate 20. A plurality of the projected portions 42 protruding toward each of the plurality of switches 22, are provided on one of the major surfaces of the key mat 40, the one of the major surfaces facing the second major surface S2 of the substrate 20. On the other major surface of the key mat 40, a plurality of the keys 16, which can be pressed down to the key mat 40, are provided. The plurality of projected portions 42 are an example of the pressure conveying portions. The keys 16 are exposed outside the case 15 passing through the through-holes 15a provided on the case 15. The battery 70 is arranged on the side of the first major surface S1 of the substrate 20 as a power source.

As for the exothermic semiconductor device 30 mounted on the first major surface S1 of the substrate 20, for example, a CPU that controls actuations of the PDA 10, other processors, or an LCD controller or the like, can be cited.

The plurality of the switches 22 provided on the second major surface S2 of the substrate 20, are so-called metal dome switches (coned disk spring-type switches), in which a metal dome (disc spring) is provided on a contact electrode (not illustrated). When the metal dome is pressed down by a downward movement of the projected part 42, which is described later, entailed by an operation of pressing down the key 16, the metal dome makes an elastic deformation toward the side of the contact electrode to finally contact it. The switch 22 is turned on/off with the contact electrode being in contact with or spaced apart from the metal dome, respectively. The structure of the switch 22 is not particularly limited hereto, but may also be a so-called membrane switch or the like.

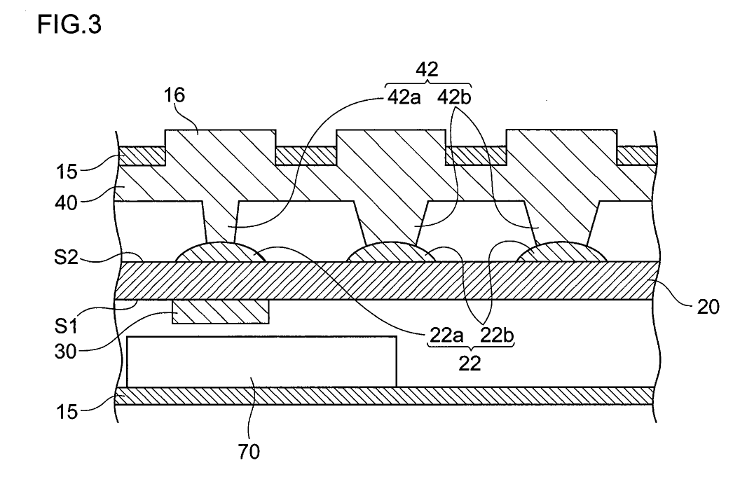

The key mat 40 is arranged on the side of the second major surface S2 of the substrate 20. The key mat 40 is made of an elastic member, such as a silicon rubber. A plurality of projected portions 42 protruding toward each of the plurality of switches 22 are provided as one body on the side of the lower face (in the drawing) of the key mat 40. A plurality of keys 16, which can be pressed down to the key mat 40, are provided on the side of the upper face (in the drawing) of the key mat 40. The keys 16 are firmly fixed to the key mat 40 by, for example, an adhesive agent. A method of allocating the keys 16 is not particularly limited hereto, but other shape may be possible in which the keys 16 and the key mat 40 are formed into one body, as illustrated in FIG. 3. In the case, the keys 16 and the key mat 40 may be formed by using, for example, a polycarbonate.

When the key 16 is pressed down, the key mat 40 makes an elastic deformation and yields, thereby forcing the projected portion 42 to move down (toward the side of the substrate 20). Due to the movement of the projected portion 42, the metal dome is pressed down to make an elastic deformation toward the side of the contact electrode, turning the switch 22 on. When the down-pressing of the key 16 is released, the key mat 40 returns to the state as it was before being pressed down, by its elasticity. Due to this, the down-pressing of the metal dome of the switch 22 is also released such that the metal dome returns to the state as it was before being pressed down, by its elasticity, turning the switch 22 off.

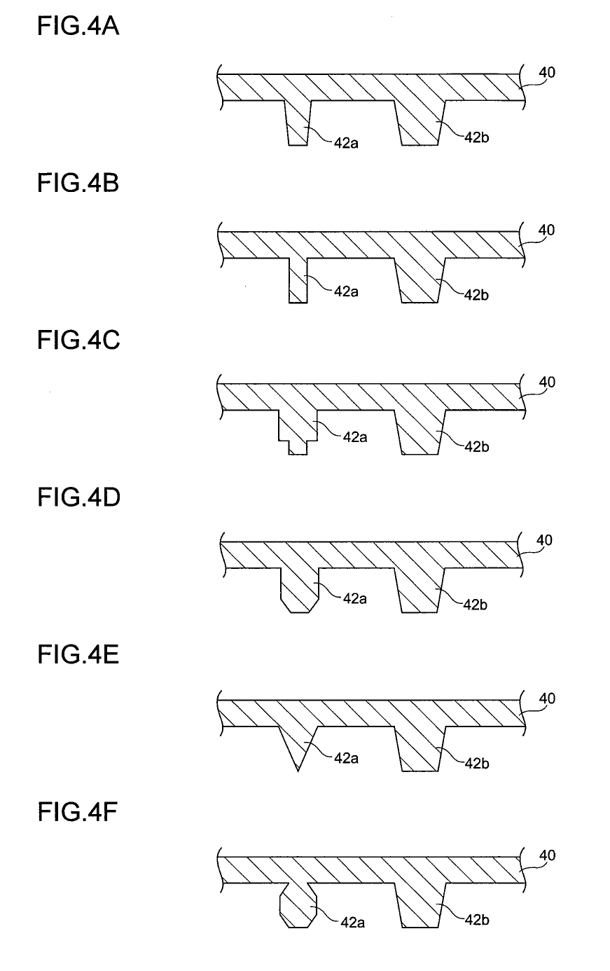

In the projected portions 42, the contact face between the particular switch 22a located within a certain range of the distance from the exothermic semiconductor device 30 in the planar direction of the substrate 20, and the projected portion protruding toward the particular switch 22a, has a smaller area as compared to that of other contact face between the non-particular switch 22b, which is a switch other than the particular switch 22a, and the projected portion 42b protruding toward the non-particular switch 22b. Specifically, the contact area between the particular switch 22a and the projected portion 42a is smaller to the extent of about one third of that between the non-particular switch 22b and the projected portion 42b. As for cross-sectional shapes of the projected portion 42a protruding toward the particular switch 22a, examples illustrated in FIGS. 4A to 4F can be cited. FIG. 4A represents a mesa type, FIG. 4B a rectangle type, FIG. 4C a convex type, FIG. 4D a taper type at the tip, FIG. 4E a triangle type, and FIG. 4F a taper type at the base and the tip.

Herein, the distance from the semiconductor device 30 means, for example, a distance from the central point of the semiconductor device 30, or a distance from the hot spot thereof where the temperature becomes the highest. Herein, the certain range means a range in which, assuming that the contact face between the particular switch 22a and the projected portion 42b protruding toward the particular switch 22a, has the same area as that between the non-particular switch 22b and the projected portion protruding toward the non-particular switch 22b, the key 16 is at a certain temperature or more, which a user of the apparatus feels hot when his/her skin, such as hand, finger, or cheek, touches the key 16, for example, while operating it, due to the heat generated by the semiconductor device 30 being conducted through the projected portion 42 to the key 16. The temperature is, for example: about 45° C. at which a low-temperature burn injury possibly occurs while contacting the key for 6 hours; about 47° C. at which the same injury possibly occurs while contacting it for 1 hour; about 50° C. at which the same injury possibly occurs while contacting it for 1 minute; or 70° C. or more at which the same injury possibly occurs while contacting it for 1 second. Alternatively, the certain range means a range in which a package including the semiconductor device 30, a chip, a wiring layer, a sealing layer, and a connecting electrode or the like, is located. Alternatively, the particular switch located within a certain range may also be a switch that is located at the smallest distance from the semiconductor device 30 in the planar direction of the substrate 20, because the heat conducted from the semiconductor device 30 to the switch becomes larger in quantity, as the distance between them is smaller.

Herein, as for the exothermic semiconductor device 30, there is also the case where a plurality of devices, such as a CPU as stated above, and an LCD controller, are present; and in the case, the above structure may be adopted with respect to the semiconductor device 30 that generates the highest heat. In the case of the PDA according to the present embodiment, the semiconductor device that generates the highest heat is a CPU.

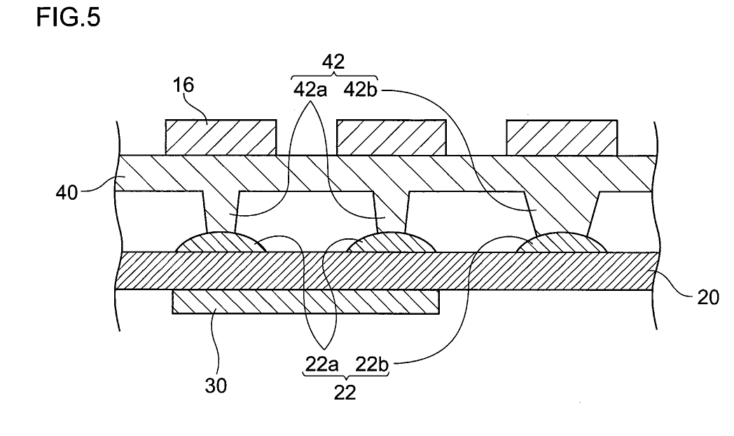

As illustrated in FIG. 5, in the case where two or more switches 22 are included within a certain distance from the semiconductor device 30, for example, in the case where two or more switches 22 that are located at the smallest distance from the semiconductor device 30, are present, the above structure may be adopted, assuming that the two or more switches 22 are the particular switches 22a. It is noted that, in FIG. 5, the case 15 and the battery 70 are omitted.

As stated above, in the present embodiment, the contact area between a particular switch 22a, which is located within a certain range of the distance from the semiconductor device 30, and the projected portion 42a protruding toward the particular switch 22a, is smaller as compared to that of other contact areas. Accordingly, the heat is difficult to be conducted through the pathway from the particular switch 22a to the projected portion 42a, as compared to that from the non-particular switch 22b to the projected portion 42b. Therefore, when the heat generated by the semiconductor device 30 is conducted from the side of the switch 22 to the side of the projected portion 42, the heat that reaches the key 16 after making a detour conducted from the non-particular switch 22b, which is located out of the certain range, to the projected portion 42b, is increased. As a result, the heat generated by the semiconductor device 30 is distributed peripherally, thereby a local rise in temperature at the key portion 16 located within a certain range from the semiconductor device 30, can be suppressed. Due to this, sweats from a user's hand or fingers occurring by key operations can be suppressed, allowing the user to operate the apparatus in a comfortable manner. Further, the poor grip performance of the apparatus can be suppressed, leading to the improved operability thereof.

### Embodiment 2

In Embodiment 1 stated above, the contact area between the particular switch 22a located within a certain distance from the semiconductor device 30, and the projected portion 42a that is engaged with the particular switch 22a, is smaller than other contact areas; but, a structure shown below may also be adopted.

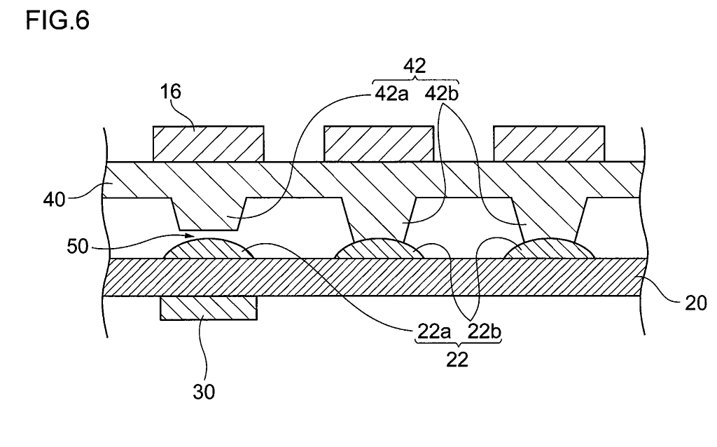

FIG. 6 is a schematic partial cross-sectional view of the apparatus directed to the present embodiment. The apparatus directed thereto is the same as the PDA 10 illustrated in FIG. 1, and FIG. 6 is a cross-sectional view taken along the same position as line “A-A” illustrated in FIG. 1. It is noted that the case 15 and the battery 70 are omitted in FIG. 6.

As illustrated in FIG. 6, in the present embodiment, the gap 50 is provided between the particular switch 22a located within a certain range of a distance from the semiconductor device 30 in the planar direction of the substrate 20, and the projected portion 42a protruding toward the particular switch 22a; and, the non-particular switch 22b and the projected portion 42b protruding toward the non-particular switch 22b, are in contact with each other. Specifically, for example, the gap 50 is provided between the particular switch 22a located at the smallest distance from the semiconductor device 30 in the planar direction of the substrate 20, and the projected portion 42a protruding toward it; and the non-particular switch 22b and the projected portion 42b protruding toward it are in contact with each other. The gap 50 has a height nearly equal to the extent in which the heat becomes difficult to be conducted from the particular switch 22a to the projected portion 42a, as compared to the case where the heat is conducted from the non-particular switch 22b to the projected portion 42b; and, has a height of, for example, about 0.1 mm.

As stated above, by providing the gap 50 between the particular switch 22a and the projected portion 42a protruding toward the particular switch 22a, it can also be made that the heat becomes difficult to be conducted through the pathway from the particular switch 22a to the projected portion 42a, as compared to the case of the pathway from the non-particular switch 22b to the projected portion 42b. Therefore, when the heat generated by the semiconductor device 30 is conducted from the side of the switch 22 to the side of the projected portion 42, the heat that reaches the key 16 after making a detour conducted from the non-particular switch 22b, which is located out of the certain range, to the projected portion 42b, is increased. As a result, the heat generated by the semiconductor device 30 is distributed peripherally, thereby a local rise in temperature at the key portion 16 located within a certain range from the semiconductor device 30, can be suppressed. Due to this, sweats from a user's hand or fingers occurring by key operations can be suppressed, allowing the user to operate the apparatus in a comfortable manner. Further, the poor grip performance of the apparatus can be suppressed, leading to the improved operability thereof.

Also in the present embodiment, in the case where two or more switches 22 are included within a certain distance from the semiconductor device 30, for example, in the case where two or more switches 22 are located at the smallest distance from the semiconductor device 30, the above structure may also be adopted, assuming that the two or more switches 22 are the particular switches 22a.

### Embodiment 3

In the present embodiment, the following structure is further provided in addition to the structure illustrated in Embodiment 1 or 2.

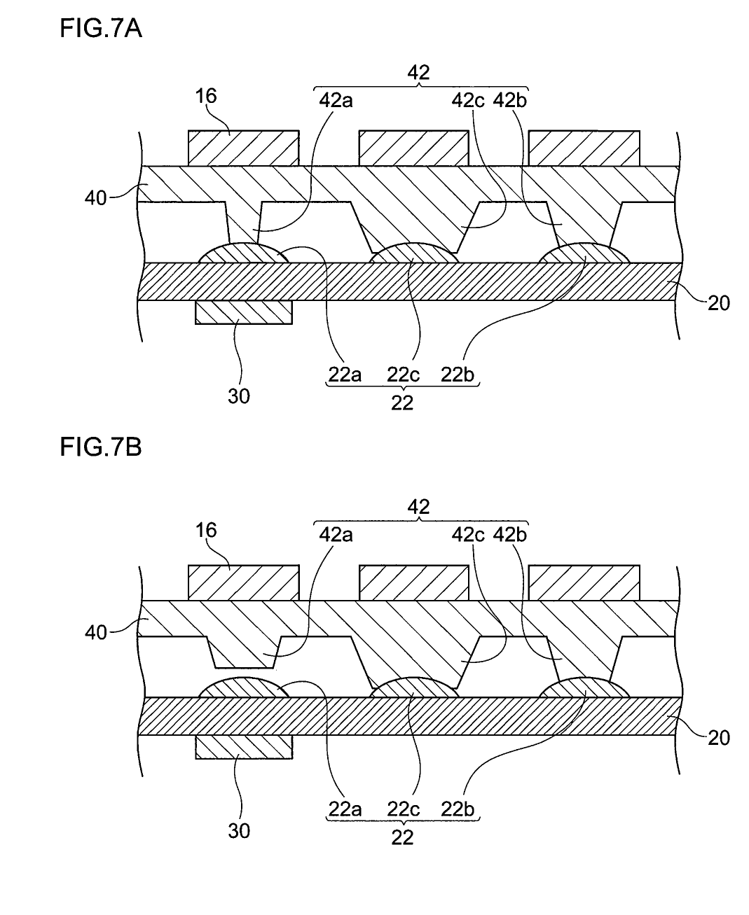

FIGS. 7A and 7B are schematic partial cross-sectional views of the apparatus directed to the present embodiment. FIG. 7A illustrates the state where the structure directed to the present embodiment is provided to the structure of Embodiment 1; and FIG. 7B illustrates the states where the structure directed to the present embodiment is provided to the structure of Embodiment 2. The apparatus directed thereto is the same as the PDA 10 illustrated in FIG. 1, and FIGS. 7A and 7B are cross-sectional views taken along the same position as line “A-A” illustrated in FIG. 1. It is noted that the case 15 and the battery 70 are omitted in FIG. 7.

As illustrated in FIG. 7A, in the present embodiment, the contact area between the particular switch 22a and the projected portion 42a protruding toward the particular switch 22a, is smaller than other area; or, as illustrated in FIG. 7B, the gap 50 is provided between the particular switch 22a and the projected portion 42a protruding toward the particular switch 22a. In addition, among the non-particular switches 22b, the contact face between the non-particular switch 22c, which is adjacent to the particular switch 22a, and the projected portion 42c protruding toward the non-particular switch 22c, has a larger area as compared to the other contact area between the other switch 22 but the non-particular switch 22c (the particular switch 22a and the non-particular switch 22b), and the projected portions 42 (projected portions 42a and 42b) protruding toward them.

As stated above, in the present embodiment, the contact area between the particular switch 22a and the projected portion 42a protruding toward it, is smaller than other contact areas, or the gap 50 is provided between them; and further, the contact area between the non-particular switch 22c, which is adjacent to the particular switch 22a, and the projected portion 42c protruding toward it, is larger than other contact areas. Therefore, the heat becomes easy to be conducted from the non-particular switch 22c, which is adjacent to the particular switch 22a, to the projected portion 42c, in addition to that the heat becomes difficult to be conducted from the particular switch 22a to the projected portion 42c. Therefore, the heat generated by the semiconductor device 30 can be introduced more effectively into the pathway conducted from the non-particular switch 22c to the projected portion 42c. As a result, a local rise in temperature at the key portion 16 located within a certain range from the semiconductor device 30, can be suppressed. Due to this, sweats from a user's hand or fingers occurring by key operations can be suppressed, allowing the user to operate the apparatus in a comfortable manner. Further, the poor grip performance of the apparatus can be suppressed, leading to the improved operability thereof.

### Embodiment 4

In each of the embodiments stated above, the descriptions have been made by taking the PDA 10 as an example of an apparatus; but, in the present embodiment, a description will be made, taking a portable phone as an example.

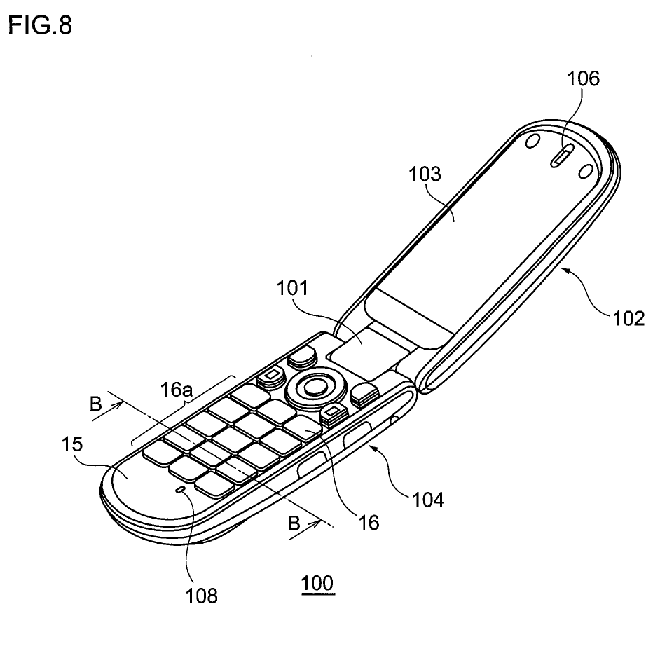

FIG. 8 is schematic view illustrating the exterior structure of the portable phone 100 directed to the present embodiment.

As illustrated in FIG. 8, the portable phone 100 has a structure in which the display unit 102 and the operating unit 104 are connected by the hinge unit 11 such that the display unit 12 and the operating unit 14 are connected pivotally through the hinge unit 11. The display panel 103 that displays characters and pictures or the like, and the speaker unit 106 are provided on the display unit 102. A plurality of keys 16 used for giving commands to execute various actuations of the portable phone 100 and for inputting characters or the like, and the microphone unit 108 are provided on the operating unit 104.

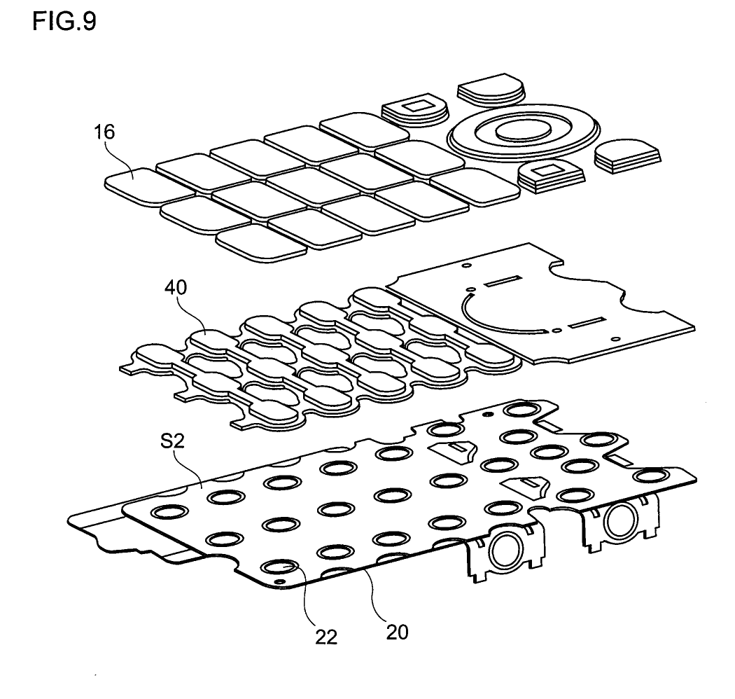

FIG. 9 is an exploded perspective view of a major structural portion of the operating unit 104 of the portable phone 100 directed to the present embodiment.

As illustrated in FIG. 9, a plurality of switches 22 that serve as connecting contact points when pressed, are provided on the second major surface S2 of the substrate 20 that is a base member. The key mat 40 made of an elastic member is arranged on the side of the second major surface S2 of the substrate 20. A plurality of projected portions (not illustrated) protruding toward each of the plurality of switches 22, are provided on one of the major surfaces (lower side in the drawing) of the key mat 40, the one of the major surface facing the second major surface of the substrate 20; and a plurality of keys 16, which can be pressed down to the key mat 40, are provided on the other side of the major surfaces (upper side in the drawing) of the key mat 40. On the other side of the second major surface S2 of the substrate 20, the semiconductor device and the battery (not illustrated) are arranged.

Also in the portable phone 100 directed to the present embodiment, the structure of each of the embodiments stated above can be adopted; and FIGS. 2, 3, and 5 to 7, are equivalent to a schematic partial cross-sectional view taken along line “B-B” of the portable phone 100 illustrated in FIG. 8. As for exothermic semiconductor devices 30 in the portable phone 100, for example, an amplifier (power amplifier), an MSM (Mobile Station Modem)(Trade Mark) or the like, can be cited.

When talking over the portable phone 100, a user talks while placing the speaker unit 106 over his/her ear and the microphone unit 108 over his/her mouth. At the time, a plurality of keys 16 provided on the operating unit 104, in particular, the numeric keypad 16a is in the state of being engaged with his/her cheek and its surrounding area. In addition, there is also the case where a conversation using the portable phone 100 continues for hours. Hence, there is the fear that, when the numeric keypad 16a is locally at a high temperature by the heat from a semiconductor device arranged inside the operating unit 104, the numeric keypad 16a, which is at a high temperature, continues to be engaged with a user's cheek and its surrounding area for long hours, resulting in the fact that a so-called low-temperature burn injury possibly occurs there.

However, by adopting the structure of each embodiment stated above to the portable phone 100 directed to the present embodiment, the heat from the semiconductor device is distributed peripherally; and thereby, a local rise in temperature at the numeric keypad 16a can be suppressed. Therefore, an effect of improving the safety of the portable phone 100 can be obtained in addition to the effects in each embodiment stated above.

### Embodiment 5

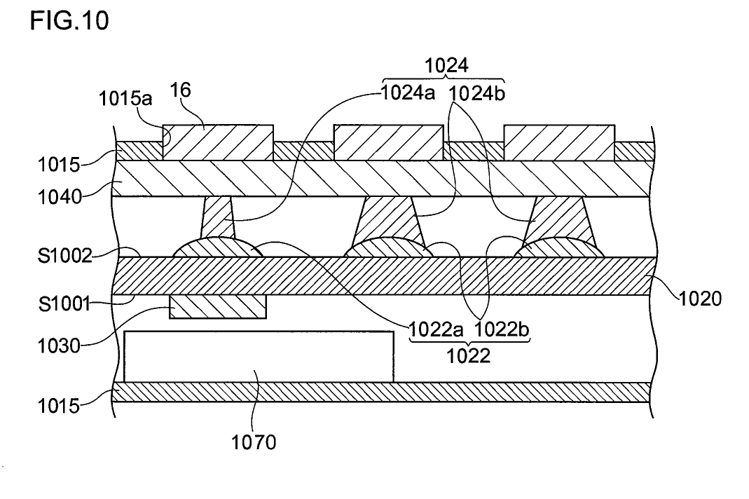

An apparatus directed to the embodiment is the same as the PDA 10 illustrated in FIG. 1, and FIG. 10 is a schematic partial cross-sectional view taken along line “A-A” of the PDA 10 illustrated in FIG. 1.

As illustrated in FIG. 10, the substrate 1020 on the first major surface S1001 of which the exothermic semiconductor device 1030 is mounted, is arranged inside the case 1015 of the operating unit of the PDA 10. The semiconductor device 1030 is an example of a heat generator, or heat releasing member. A plurality of switches 1022, which serve as connecting contact points when pressed, are provided on the second major surface S1002 on the other side of the first major surface S1001 of the substrate 1020. The key mat 1040 made of an elastic member is arranged on the side of the second major surface S1002 of the substrate 1020. A plurality of projected portions 1024 protrude from each of the plurality of switches 1022 toward one of major surfaces of the key mat 1040, the one of major surfaces facing the second major surface S1002 of the substrate 1020. The plurality of projected portions 1024 is an example of the pressure conveying portions. A plurality of keys 16, which can be pressed down to the key mat 1040, are provided on the other major surface of the key mat 1040. The keys 16 are exposed outside the case 1015 passing through the through-holes 1015a provided on the case 1015. The battery 1070 is arranged on the side of the first major surface S1001 of the substrate 1020 as a power source.

As for the exothermic semiconductor device 1030 mounted on the first major surface S1001 of the substrate 1020, for example, a CPU that controls actuations of the PDA 10, other processors, or an LCD controller or the like, can be cited.

The plurality of the switches 1022 provided on the second major surface S1002 of the substrate 1020, are so-called metal dome switches (coned disk spring-type switches), in which a metal dome (disc spring) is provided on a contact electrode (not illustrated). When the metal dome is pressed down by a downward movement of the projected part 1024, which is described later, entailed by an operation of pressing down the key 16, the metal dome makes an elastic deformation toward the side of the contact electrode to finally contact the contact electrode. The switch 1022 is turned on/off with the contact electrode being in contact with or spaced apart from the metal dome, respectively. The structure of the switch 1022 is not particularly limited hereto, but may also be a so-called membrane switch or the like.

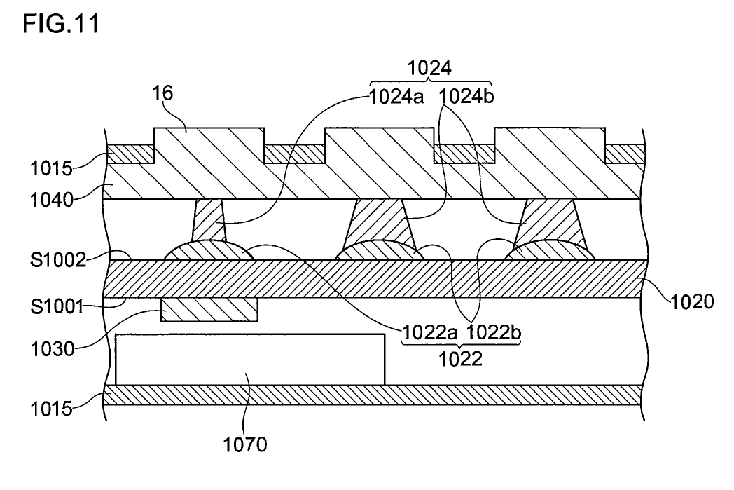

The key mat 1040 is arranged on the side of the second major surface S1002 of the substrate 1020. The key mat 1040 is made of an elastic members, such as a silicon rubber. A plurality of projected portions 1024 protrude from each of the plurality of switches 1022 toward the key mat 1040. The projected portion 1024 are made of, for example, a silicon rubber, in a similar way as with the key mat 1040, and are firmly fixed to the switches 1022. A plurality of keys 16, which can be pressed down to the key mat 1040, are provided at positions corresponding to each of the plurality of projected portions 1024, on the side of the upper surface (in the drawing) of the key mat 1040. The keys 16 are firmly fixed to the key mat 1040 by, for example, an adhesive agent. A method of allocating the keys 16 is not particularly limited hereto, but other shape may also be possible in which the keys 16 and the key mat 1040 are formed into one body, as illustrated in FIG. 11. In the case, the keys 16 and the key mat 1040 may be formed by using, for example, a polycarbonate.

When the key 16 is pressed down, the key mat 1040 makes an elastic deformation and yields, thereby forcing the projected portion 1024 to move down (toward the side of the substrate 1020). Due to an action of pressing down the projected portion 1024, the metal dome is pressed down to make an elastic deformation toward the side of the contact electrode, turning the switch 1022 on. When the down-pressing of the key 16 is released, the key mat 1040 returns to the state as it was before being pressed down, by its elasticity. Due to this, the down-pressing of the projected portion 1024 is also released such that the metal dome returns to the state as it was before being pressed down, by its elasticity, turning the switch 1022 off.

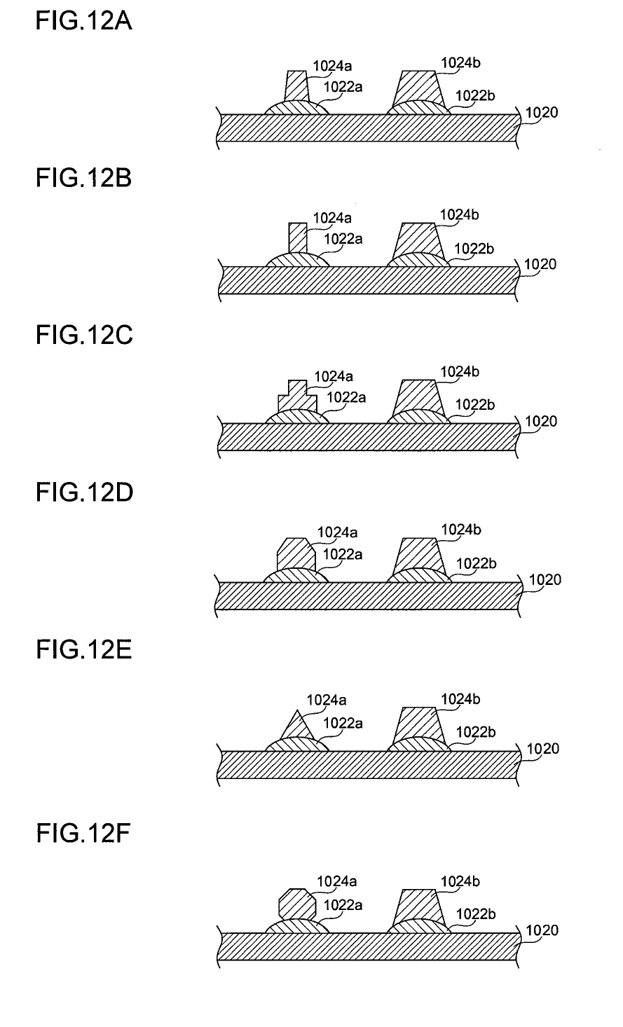

In the projected portions 1024, the contact face between the projected portion 1024a protruding from the particular switch 1022a located within a certain range of the distance from the exothermic semiconductor device 30 in the planar direction of the substrate 1020, and the key mat 1040, has a smaller area as compared to that of other contact face between the projected portion protruding from the non-particular switch 1022b, which is a switch other than the particular switch 1022a, and the key mat 1040. Specifically, the contact area between the projected portion 1024a protruding from the particular switch 1022a, and the key mat 1040, is smaller to the extent of about one third of that between the projected portion 1024b protruding from the non-particular switch 1022b and the key mat 1040. As shapes of the projected portion 1024a protruding from the particular switch 1022a, examples illustrated in FIGS. 12A to 12F can be cited. FIG. 12A represents a mesa type, FIG. 12B a rectangle type, FIG. 12C a convex type, FIG. 12D a taper type at the tip, FIG. 12E a triangle type, and FIG. 12F a taper type at the base and the tip.

Herein, the distance from the semiconductor device 1030 means, for example, a distance from the central point of the semiconductor device 1030, or a distance from the hot spot thereof where the temperature becomes the highest. Herein, the certain range means a range in which, assuming that the contact face between the projected portion 1024a protruding from the particular switch 1022a, and the key mat 1040, has the same area as that between the projected portion 1024b protruding from the non-particular switch 1022b, and the key mat 1040, the key 16 is at a certain temperature or more, which a user of the apparatus feels hot when his/her skin, such as hand, finger, or cheek, touches the key 16, for example, while operating it, due to the heat generated by the semiconductor device 1030 being conducted through the projected portion 1024 to the key 16. The temperature is, for example: about 45° C. at which a low-temperature burn injury possibly occurs while contacting the key for 6 hours; about 47° C. at which the same injury possibly occurs while contacting it for 1 hour; about 50° C. at which the same injury possibly occurs while contacting it for 1 minute; or 70° C. or more at which the same injury possibly occurs while contacting it for 1 second. Alternatively, the certain range means a range in which a package including the semiconductor device 1030, a chip, a wiring layer, a sealing layer, and a connecting electrode or the like, is located. Alternatively, the particular switch located within a certain range may also be a switch that is located at the smallest distance from the semiconductor device 1030 in the planar direction of the substrate 1020, because the heat conducted from the semiconductor device 1030 to the switch becomes larger in quantity, as the distance between them is smaller.

Herein, as for the exothermic semiconductor device 1030, there is also the case where a plurality of devices, such as a CPU as stated above, and an LCD controller, are present; and in the case, the above structure may also be adopted with respect to the semiconductor device 1030 that generates the highest heat. In the case of the PDA according to the present embodiment, the semiconductor device that generates the highest heat is a CPU.

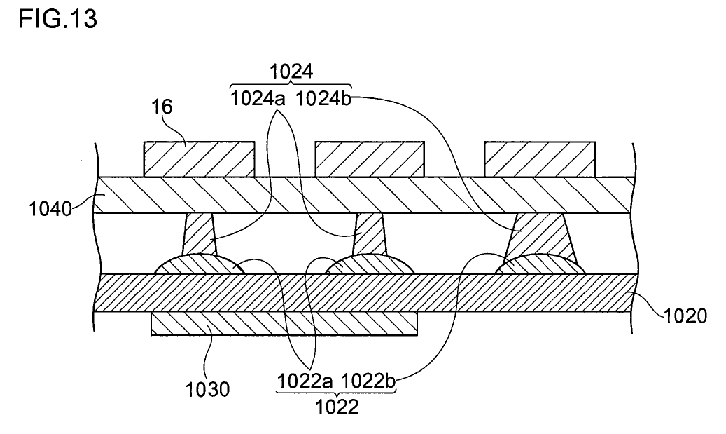

As illustrated in FIG. 13, in the case where two or more switches 1022 are included within a certain distance from the semiconductor device 1030, for example, in the case where two or more switches 1022 located at the smallest distance from the semiconductor device 1030, are present, the above structure may be adopted, assuming that the two or more switches 1022 are the particular switches 1022a. It is noted that, in FIG. 13, the case 1015 and the battery 1070 are omitted.

As stated above, in the present embodiment, the contact area between the projected portion 1024a protruding from a certain particular switch 1022a, which is located within a certain range of the distance from the semiconductor device 1030, and the key mat 1040, is smaller as compared to that of other contact areas. Accordingly, the heat is difficult to be conducted through the pathway from the projected portion 1024a to the key mat 1040, as compared to that from the projected portion 1024b to the key mat 1040. Therefore, when the heat generated by the semiconductor device 1030 is conducted from the side of the projected portion 1024 to the side of the key mat 1040, the heat that reaches the key 16 after making a detour conducted from the projected portion 1024b to the key mat 1040, is increased. As a result, the heat generated by the semiconductor device 1030 is distributed peripherally; and thereby a local rise in temperature at the key portion 16 located within a certain range from the semiconductor device 1030, can be suppressed. Due to this, sweats from a user's hand or fingers occurring by key operations can be suppressed, allowing the user to operate the apparatus in a comfortable manner. Further, the poor grip performance of the apparatus can be suppressed, leading to the improved operability thereof.

### Embodiment 6

In Embodiment 5 stated above, the contact area between the projected portion 1024a protruding from the particular switch 1022a located within a certain distance from the semiconductor device 1030, and the key mat 1040, is smaller than other contact areas; but, a structure shown below may be also be adopted.

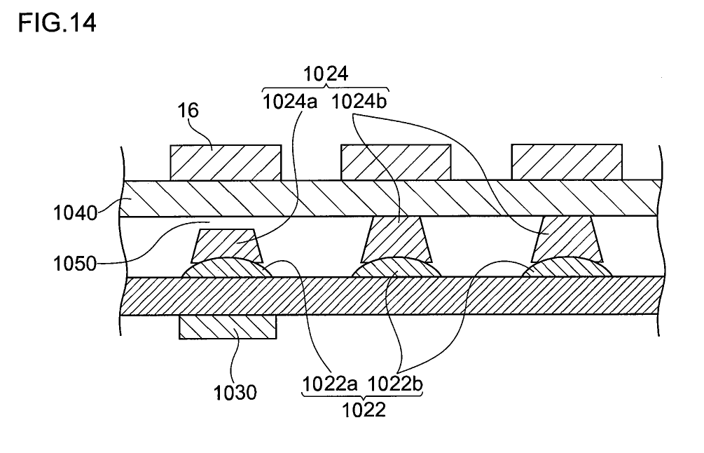

FIG. 14 is a schematic partial cross-sectional view of an apparatus directed to the present embodiment. The apparatus directed thereto is the same as the PDA 10 illustrated in FIG. 1, and FIG. 14 is a cross-sectional view taken along the same position as line “A-A” illustrated in FIG. 1. It is noted that the case 1015 and the battery 1070 are omitted in FIG. 14.

As illustrated in FIG. 14, in the present embodiment, the gap 1050 is provided between the projected portion 1024a protruding from the particular switch 1022a located within a certain range of the distance from the semiconductor device 1030 in the planar direction of the substrate 1020, and the key mat 1040; and, the projected portion 1024b protruding from the non-particular switch 1022b, and the key mat 1040, are in contact with each other. Specifically, for example, the gap 1050 is provided between the projected portion 1024a protruding from the particular switch 1022a located at the smallest distance from the semiconductor device 1030 in the planar direction of the substrate 1020, and the key mat 1040; and the projected portion 1024b protruding from the non-particular switch 1022b and the key mat 1040, are in contact with each other.

The gap 1050 has a height nearly equal to the extent in which the heat becomes difficult to be conducted from the projected portion 1024a protruding from the particular switch 1022a, to the key mat 1040, as compared to the case where the heat is conducted from the projected portion 1024b protruding from the non-particular switch 1022b, to the key mat 1040; and, has a height of, for example, about 0.1 mm.

As stated above, by providing the gap 1050 between the projected portion 1024a protruding from the particular switch 1022a and the key mat 1040, it can also be made that the heat becomes difficult to be conducted through the pathway from the projected portion 1024a to the key mat 1040, as compared to the case of the pathway from the projected portion 1024b to the key mat 1040. Therefore, when the heat generated by the semiconductor device 1030 is conducted from the side of the projected portion 1024 to the side of the key mat 1040, the heat that reaches the key 16 after making a detour conducted from the projected portion 1024b to the key mat 1040, is increased. As a result, the heat generated by the semiconductor device 1030 is distributed peripherally; and thereby, a local rise in temperature at the key portion 16 located within a certain range from the semiconductor device 1030, can be suppressed. Due to this, sweats from a user's hand or fingers occurring by key operations can be suppressed, allowing the user to operate the apparatus in a comfortable manner. Further, the poor grip performance of the apparatus can be suppressed, leading to the improved operability thereof.

Also in the present embodiment, in the case where two or more switches 1022 are included within a certain distance from the semiconductor device 1030, for example, in the case where two or more switches 1022 located at the smallest distance from the semiconductor device 1030, are present, the above structure may also be adopted, assuming that the two or more switches 1022 are the particular switches 1022a.

### Embodiment 7

In the present embodiment, the following structure is further provided in addition to the structure illustrated in Embodiment 5 or 6.

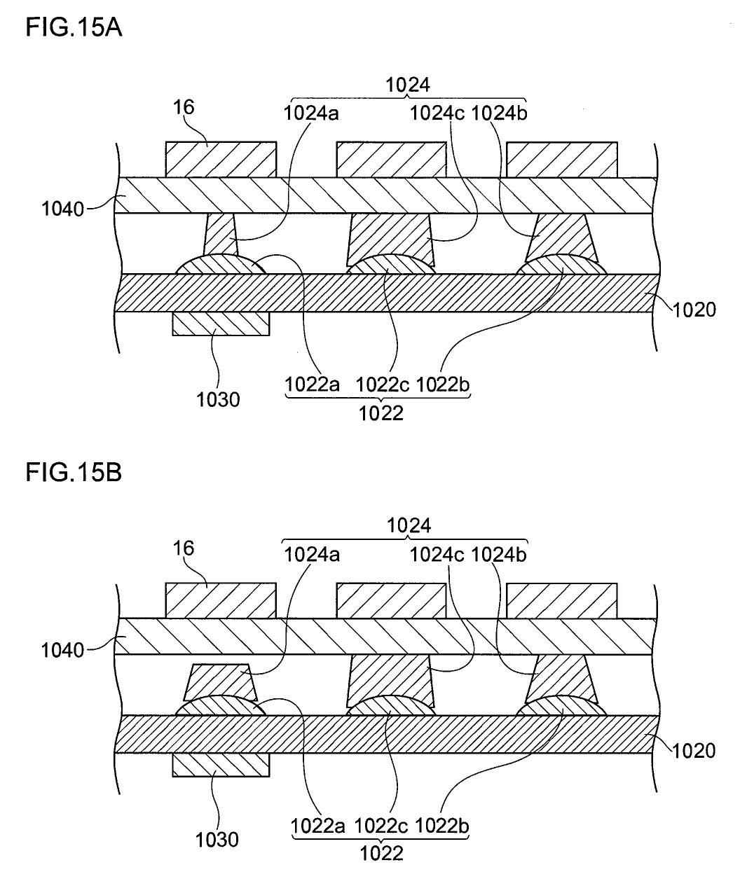

FIGS. 15A and 15B are schematic partial cross-sectional views of an apparatus directed to the present embodiment. FIG. 15A illustrates the state where the structure directed to the present embodiment is provided to the structure of Embodiment 5; and FIG. 15B illustrates the states where the structure directed to the present embodiment is provided to the structure of Embodiment 6. The apparatus directed thereto is the same as the PDA 10 illustrated in FIG. 1, and FIGS. 15A and 15B are cross-sectional views taken along the same position as line “A-A” illustrated in FIG. 1. It is noted that the case 1015 and the battery 1070 are omitted in FIG. 15.

As illustrated in FIG. 15A, in the present embodiment, the contact area between the projected portion 1024a protruding from the particular switch 1022a and the key mat 1040, is smaller than other area; or, as illustrated in FIG. 15B, the gap 1050 is provided between the projected portion 1024a protruding from the particular switch 1022a and the key mat 1040. In addition, among the non-particular switches 1022b, the contact face between the projected portion 1024c protruding from the non-particular switch 1022c, which is adjacent to the particular switch 1022a, and the key mat 1040, has a larger area as compared to the other contact face between the projected portion 1024 (the projected portion 1024a and the projected portion 1024b) protruding from the other switch 1022 but the non-particular switch 1022c (the particular switch 1022a and the non-particular switch 1022b), and the key mat 1040.

As stated above, in the present embodiment, the contact area between the projected portion 1024a protruding from the particular switch 1022a and the key mat 1040, is smaller than other contact areas; or the gap 1050 is provided between them, and the contact area between the projected portion 1024c protruding from the non-particular switch 1022c, which is adjacent to the particular switch 1022a, and the key mat 1040, is further larger than other contact areas. Therefore, the heat becomes easy to be conducted from the projected portion 1024c protruding from the non-particular switch 1022c, which is adjacent to the particular switch 1022a, to the key mat 1040, in addition to that the heat becomes difficult to be conducted from the projected portion 1024a protruding from the particular switch 1022a, to the key mat 1040. Therefore, the heat generated by the semiconductor device 1030 can be introduced more effectively into the pathway conducted from the projected portion 1024c to the key mat 1040. As a result, a local rise in temperature at the key portion 16 located within a certain range from the semiconductor device 1030, can be suppressed. Due to this, sweats from a user's hand or fingers occurring by key operation can be suppressed, allowing the user to operate the apparatus in a comfortable manner. Further, the poor grip performance of the apparatus can be suppressed, leading to the improved operability thereof.

### Embodiment 8

In each of the embodiments stated above, the descriptions have been made by taking the PDA 10 as an example of an apparatus; but, in the present embodiment, a description will be made, taking a portable phone as an example.

A portable phone directed to the present embodiment has the same exterior structure as with the portable phone 100 illustrated in FIG. 8. Accordingly, the same structure is denoted by the same reference numeral as that of FIG. 8, and the duplicative descriptions will be appropriately omitted.

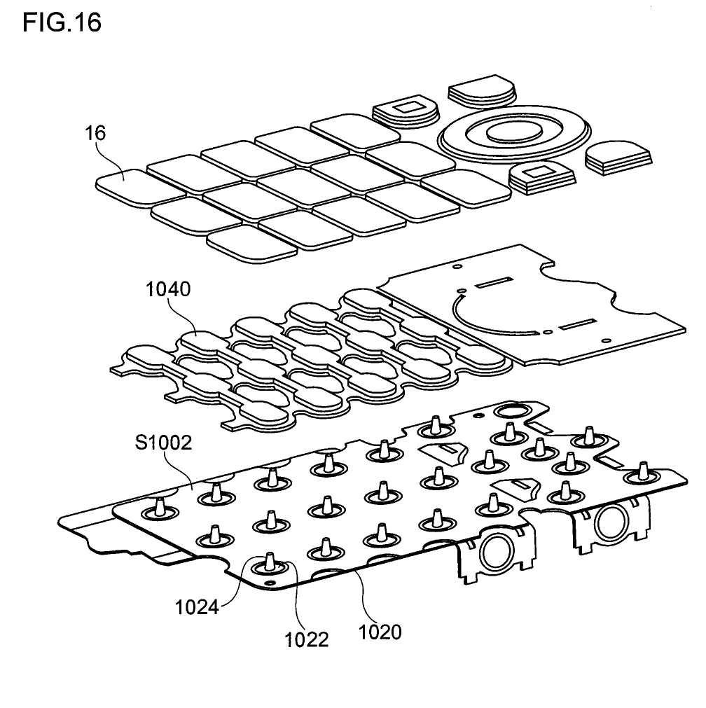

FIG. 16 is an exploded perspective view illustrating a major structural portion of the operating unit 104 of the portable phone 100 directed to the present embodiment.

As illustrated in FIG. 16, a plurality of switches 1022, which serve as connecting contact points when pressed, are provided on the second major surface S1002 of the substrate 1020 that is a base member. A plurality of projected portions 1024 protrude from the plurality of switches 1022 toward the upper direction in the drawing (toward a key mat 1040). The key mat 1040 made of an elastic member is arranged on the side of the second major surface S1002 of the substrate 1020. A plurality of keys 16, which can be pressed down to the key mat 1040, are provided on the major surface of the key mat 1040 (upper direction in the drawing), the major surface being opposite to the substrate 1020. The semiconductor device and the battery (not illustrated) are arranged on the opposite side of the substrate 1020, the side being opposite to the second major surface S1002 of the substrate 1020.

Also in the portable phone 100 directed to the present embodiment, the structure of each of the embodiments stated above may also be adopted; and FIGS. 10, 11, and 13 to 15, are equivalent to a schematic partial cross-sectional view taken along line “B-B” of the portable phone 100 illustrated in FIG. 8. As for exothermic semiconductor devices 1030 in the portable phone 100, for example, an amplifier (power amplifier), an MSM (Mobile Station Modem)(Trade Mark) or the like, can be cited.

When talking over the portable phone 100, a user talks while placing the speaker unit 106 over his/her ear and the microphone unit 108 over his/her mouth. At the time, a plurality of keys 16 provided on the operating unit 104, in particular, the numeric keypad 16a is in the state of being engaged with his/her cheek and its surrounding area. In addition, there is also the case where a conversation using a portable phone 100 continues for hours. Hence, there is the fear that, when the numeric keypad 16a is locally at a high temperature by the heat from a semiconductor device arranged inside the operating unit 104, the numeric keypad 16a, which is at a high temperature, continues to be engaged with a user's cheek and its surrounding area for long hours, resulting in the fact that a so-called low-temperature burn injury possibly occurs.

However, by adopting the structure of each embodiment stated above to the portable phone 100 directed to the present embodiment, the heat from the semiconductor device is distributed peripherally; and thereby, a local rise in temperature at the numeric keypad 16a can be suppressed. Therefore, an effect of improving the safety of the portable phone 100 can be obtained in addition to the effects in each embodiment stated above.

The present invention should not be limited to each of the above embodiments, and various modifications, such as design modifications, may be made based on knowledge of a person skilled in the art. Embodiments to which such modifications are added should also fall within the scope of the present invention.

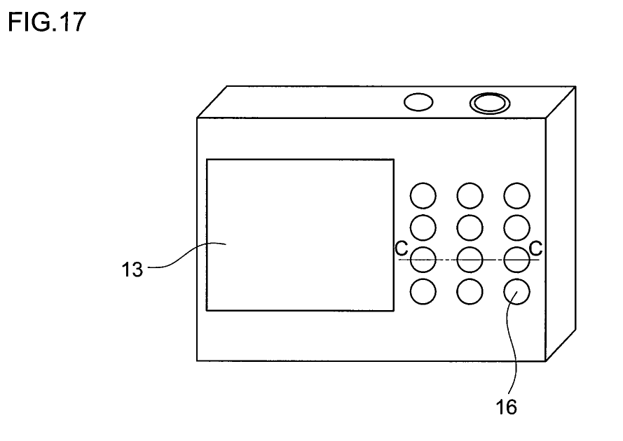

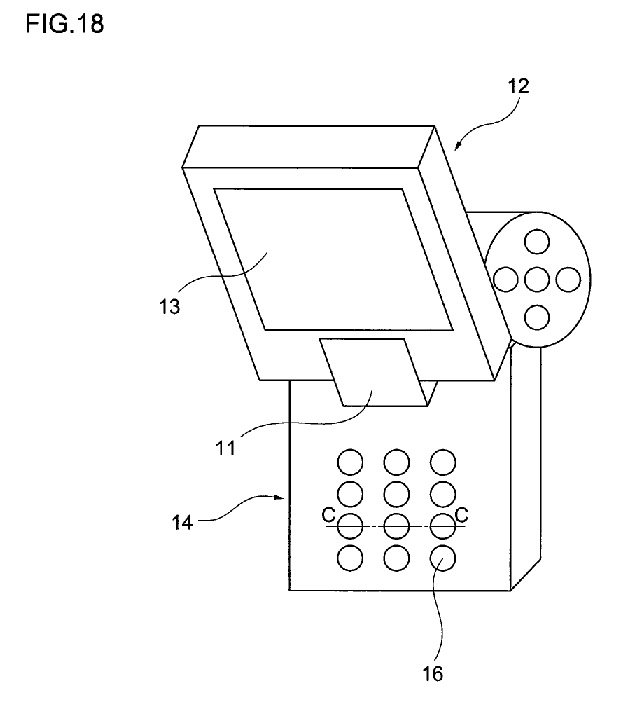

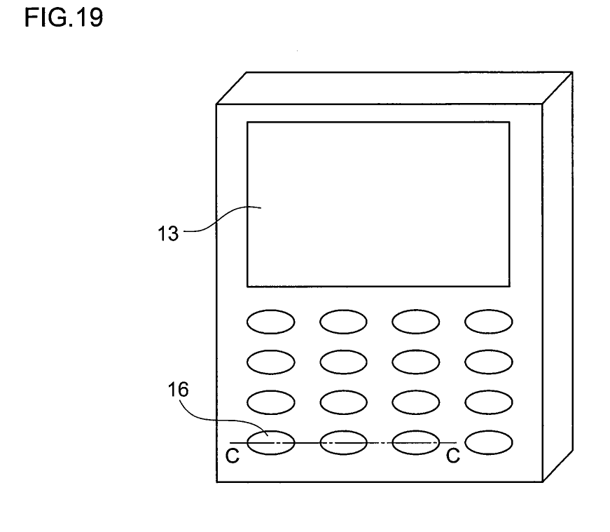

The structure illustrated, for example, in each of the above embodiments, cab be applicable to the apparatuses, such as a digital still camera illustrated in FIG. 17, a digital camcorder illustrated in FIG. 18, and a non-folded electronic dictionary and electronic note book illustrated in FIG. 19, or the like. FIGS. 2, 3, 5 to 7, 10, 11, and 13 to 15 are equivalent to schematic partial cross-sectional views taken along line “C-C” illustrated in each drawing. As for the exothermic semiconductor devices 30 and 1030 in a digital still camera and a digital camcorder camera, for example, a CPU that controls actuations, a power source unit, a CCD, and a CCD drive circuit or the like, can be cited. As for the exothermic semiconductor devices 30 and 1030 in an electronic dictionary and electronic notebook, for example, a CPU that controls actuations, other processors, an LCD controller or the like, can be cited. The semiconductor devices 30 and 1030 may also be other things stated herein. Among exothermic semiconductor devices mounted in a digital still camera, digital camcorder, electronic dictionary, and electronic notebook, the semiconductor device that generates the highest heat is a CPU.

In each of the above embodiments, the plurality of keys are respectively fixed to the key mat as separate bodies; however, the keys may also be key sheet-shaped, in which a plurality of keys are formed into one body. In the case, part of the case of the apparatus may also be composed of the key sheet.

In each of above Embodiments 1 to 4, the projected portions are provided on the key mat; however, the following structure may also be adopted, in which: the keys and the projected portions are formed into one body; the projected portions are inserted through the through-holes of the key sheet, which are penetrated at positions corresponding to each of the switches; and the keys are held by the key sheet.

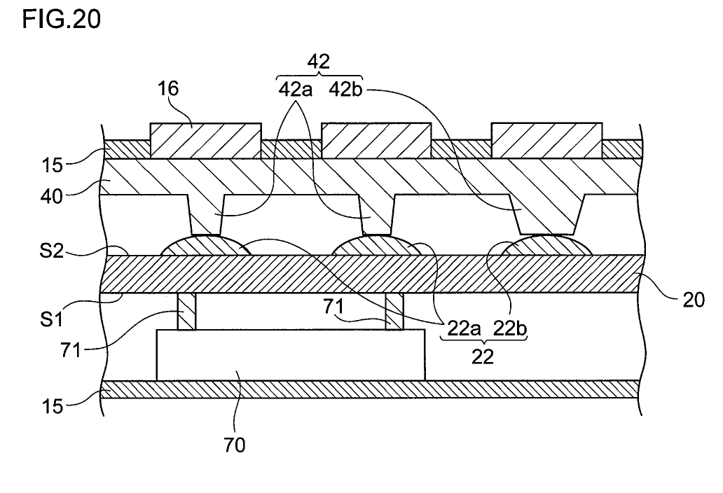

In each of above Embodiments 1 to 4, the descriptions have been made, taking the semiconductor device as an example of a heat generator; however, for example, a battery as a power source can be a heat generator, or heat releasing member. As illustrated in FIG. 20, in the structure in which the battery 70 is arranged on the side of the first major surface S1 of the substrate 20, the battery 70 is provided on the substrate 20 via a plurality of spacers 71. In the case, the heat generated by the battery 70 is conducted to the side of the substrate 20 via the spacer 71. Hence, assuming that the switch 22 located within a certain range of the distance from the spacer 71 in the planar direction of the substrate 20, for example, the switch 22 located at the smallest distance from the spacer 71, is the particular switch 22a, a contact area between the particular switch 22a and the projected portion 42a protruding toward the particular switch 22a, is smaller than other areas. In addition, without the contact area between the particular switch 22a and the projected portion 42a being smaller, the structure illustrated in each of above Embodiments 1 to 4 may be adopted appropriately, for example, with a gap being provided.

By adopting the structures stated above, a local rise in temperature at the key 16 portion located within a certain range from the spacer 71, which is provided between the battery 70 and the substrate 20, can be suppressed. Due to this, sweats from a user's hand or fingers occurring by key operations can be suppressed, allowing the user to operate the apparatus in a comfortable manner. Further, the poor grip performance of the apparatus can be suppressed, leading to the improved operability thereof.

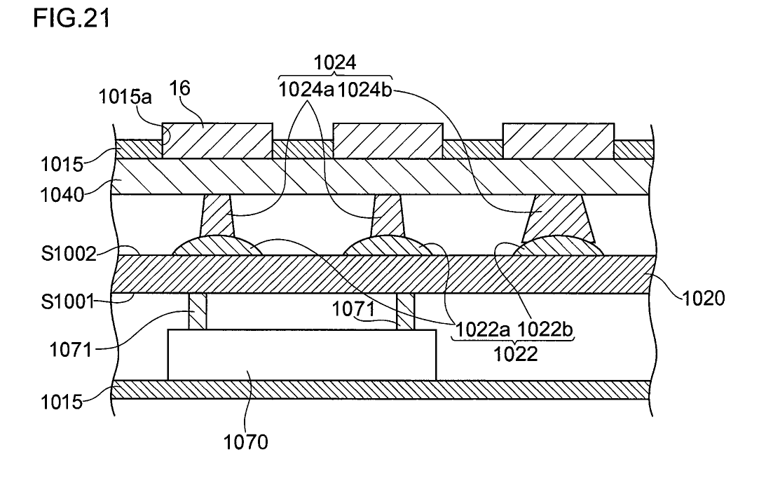

In each of above Embodiments 5 to 8, the descriptions have been made, taking the semiconductor device as an example of a heat generator; however, for example, a battery as a power source can be a heat generator, or heat releasing member. As illustrated in FIG. 21, in the structure in which the battery 1070 is arranged on the side of the first major surface S1001 of the substrate 1020, the battery 1070 is provided on the substrate 1020 via a plurality of spacers 1071. In the case, the heat generated by the battery 1070 is conducted to the side of the substrate 1020 via the spacers 1071. Hence, assuming that the switch 1022 located within a certain range of the distance from the spacer 1071 in the planar direction of the substrate 1020, for example, the switch 1022 located at the smallest distance from the spacer 1071, is the particular switch 1022a, a contact area between the particular switch 1022a and the projected portion 1024a protruding from the particular switch 1022a, is smaller than other areas. In addition, without the contact area between the particular switch 1022a and the projected portion 1024a being smaller, the structure illustrated in each of above Embodiments 5 to 8 may be adopted appropriately, for example, with a gap being provided.

By adopting the structures stated above, a local rise in temperature at the key portion 16 located within a certain range from the spacer 1071, which is provided between the battery 1070 and the substrate 1020, can be suppressed. Due to this, sweats from a user's hand or fingers occurring by key operations can be suppressed, allowing the user to operate the apparatus in a comfortable manner. Further, the poor grip performance of the apparatus can be suppressed, leading to the improved operability thereof.

What is claimed is:

1. An apparatus comprising:
a substrate;
a heat generator provided directly or via a spacer on a first major surface of the substrate;
a plurality of switches that are provided on a second major surface of the substrate and that serve as connecting a contact point when pressed;
a key mat that is located on the side of the second major surface of the substrate and made of an elastic member;
a plurality of pressure conveying portions that are provided at positions corresponding to each of the plurality of switches, and are provided between the second major surface of the substrate and one of the major surfaces of the key mat, the one of major surfaces facing the second major surface of the substrate; and
a key that is provided on the other major surface of the key mat and that can be pressed down to the key mat, wherein a contact face between the pressure conveying portion corresponding to a particular switch located within a certain range of the distance from the heat generator directly fixed to the substrate or from the spacer, in the planar direction of the substrate, and the particular switch, has a smaller area as compared to that of a contact face between the pressure conveying portion corresponding to a non-particular switch, which is a switch other than the particular switch, and the non-particular switch; or wherein a contact face between the pressure conveying portion corresponding to the particular switch and the key mat, has a smaller area as compared to that of a contact face between the pressure conveying portion corresponding to the non-particular switch and the key mat.

2. The apparatus according to claim 1, wherein the plurality of pressure conveying portions are a plurality of projected portions protruding from one of the major surfaces of the key mat, the one of the major surface facing the second major surface of the substrate, toward each of the plurality of switches; and wherein a contact face between the particular switch located within a certain range of the distance from the heat generator directly fixed to the substrate or from the spacer, in the planar direction of the substrate, and a projected portion protruding toward the particular switch, has a smaller area as compared to that of a contact face between the non-particular switch, which is a switch other than the particular switch, and the projected portion protruding toward the non-particular switch.

3. The apparatus according to claim 1, wherein the plurality of pressure conveying portions are a plurality of projected portions protruding from each of the plurality of switches toward one of the major surfaces of the key mat, the one of the major surfaces facing the second major surface of the substrate; and wherein a contact face between the projected portion protruding from the particular switch located within a certain range of the distance from the heat generator directly fixed to the substrate or from the space, in the planar direction of the substrate, and the key mat, has a smaller area as compared to that of a contact face between the projected portion protruding from the non-particular switch, which is a switch other than the particular switch, and the key mat.

4. The apparatus according to claim 1, wherein the heat generator is an exothermic semiconductor device.

5. The apparatus according to claim 1, wherein the heat generator is a power source.

6. An apparatus comprising:
a substrate;
a heat generator provided directly or via a spacer on a first major surface of the substrate;
a plurality of switches that are provided on a second major surface of the substrate, and that serve as connecting a contact point when pressed;
a key mat that is located on the side of the second major surface of the substrate and made of an elastic member;
a plurality of pressure conveying portions that are provided at positions corresponding to each of the plurality of switches, and are provided between the second major surface of the substrate and one of the major surfaces of the key mat, the one of the major surfaces facing the second major surface of the substrate; and
a key that is provided on the other side of the major surface of the key mat, and that can be pressed down to the key mat, wherein a gap is provided between the pressure conveying portion corresponding to the particular switch located within a certain range of the distance from the generator directly fixed to the substrate or from the spacer, in the planar direction of the substrate, and the particular switch or the key mat; and wherein the pressure conveying portion corresponding to the non-particular switch, which is a switch other than the particular switch, is in contact with the non-particular switch and the key mat.

7. The apparatus according to claim 6, wherein the plurality of pressure conveying portions are a plurality of projected portions protruding from the one of the major surfaces of the key mat, the one of the major surfaces facing the second major surface of the substrate, toward each of the plurality of switches; and wherein a gap is provided between the particular switch located within a certain range of the distance from the heat generator directly fixed to the substrate or from the space, in the planar direction of the substrate, and the projected portion protruding toward the particular switch, and wherein the non-particular switch, which is a switch other than the particular switch, and the projected portion protruding toward the non-particular switch are in contact with each other.

8. The apparatus according to claim 6, wherein the plurality of pressure conveying portions are a plurality of projected portions protruding from each of the plurality of switches toward one of the major surfaces of the key mat, the one of the major surfaces facing the second major surface of the substrate; and wherein a gap is provided between the projected portion protruding from the particular switch located within a certain distance from the heat generator directly fixed to the substrate or from the spacer, in the planar direction of the substrate, and the key mat, and wherein the projected portion protruding from the non-particular switch, which is a switch other than the particular switch, and the key mat are in contact with each other.

9. The apparatus according to claim 6, wherein the heat generator is an exothermic semiconductor device.

10. The apparatus according to claim 6, wherein the heat generator is a power source.

11. The apparatus according to claim 1, wherein the particular switch located within a certain range is a switch that is located at the smallest distance from the heat generator directly fixed to the substrate or from the spacer, in the planar direction of the substrate.

12. The apparatus according to claim 6, wherein the particular switch located within a certain range is a switch that is located at the smallest distance from the heat generator directly fixed to the substrate or from the spacer, in the planar direction of the substrate.

13. The apparatus according to claim 1, wherein a contact face between the pressure conveying portion corresponding to the non-particular switch that is adjacent to the particular switch, and the non-particular switch, has a larger area as compared to that of a contact face between the pressure conveying portion corresponding to other switch, and the other switch; or wherein a contact face between the pressure conveying portion corresponding the non-particular switch, and the key mat, has a larger area as compared to that of a contact face between the pressure conveying portion corresponding to other switch and the key mat.

14. The apparatus according to claim 6, wherein a contact face between the pressure conveying portion corresponding to the non-particular switch that is adjacent to the particular switch, and the non-particular switch, has a larger area as compared to that of a contact face between the pressure conveying portion corresponding to other switch, and the other switch; or wherein a contact face between the pressure conveying portion corresponding to the non-particular switch and the key mat, has a larger area as compared to that of a contact face between the pressure conveying portion corresponding to other switch and the key mat.
